(19) United States
(12) Patent Application Publication
(10) Pub. No.: US 2026/0353697 A1
(43) Pub. Date: Nov. 5, 2026

(54) SEMICONDUCTOR DEVICE INCLUDING TWO-DIMENSIONAL MATERIAL

(71) Applicant: Samsung Electronics Co., Ltd., Suwon-si (KR)

(72) Inventors: Jaekang Koh, Suwon-si (KR); Jongwon Lee, Suwon-si (KR); Jungpyo Hong, Suwon-si (KR)

(21) Appl. No.: 19/578,293

(22) Filed: Mar. 25, 2026

(30) Foreign Application Priority Data
Apr. 30, 2025 (KR) 10-2025-0057293

(51) Int. Cl. H10D 30/47; H10D 30/00; H10D 62/80; H10D 64/62; H10D 64/68; H10D 30/01

(52) U.S. Cl. CPC H10D 30/481; H10D 30/502; H10D 62/881; H10D 62/882; H10D 62/883; H10D 64/62; H10D 64/685; H10D 64/691; H10D 30/017; H10D 30/0191

(57) ABSTRACT

A semiconductor device may include a base layer, a plurality of channel regions spaced apart from an upper surface of the base layer and from each other in a vertical direction perpendicular to an upper surface of the base layer, the plurality of channel regions including a two-dimensional material, and having p-type conductivity, and a gate structure including a first gate layer and a second gate layer. The first gate layer may include a metal chloride, and the first gate layer may contact and may surround surfaces of the plurality of channel regions. The second gate layer may include a metal included in the first gate layer, and the second gate layer may surround a surface of the first gate layer.

### CROSS-REFERENCE TO RELATED APPLICATION

This application claims priority under 35 USC § 119 to Korean Patent Application No. 10-2025-0057293, filed on Apr. 30, 2025, in the Korean Intellectual Property Office (KIPO), the contents of which are incorporated by reference herein in their entirety.

### BACKGROUND

Various example embodiments relate to a semiconductor device. Particularly, various example embodiments relate to a semiconductor device including two-dimensional (2D) material.

Silicon may be generally used as a channel layer of a transistor. However, it is difficult to form silicon with a small thickness while maintaining crystallinity. Therefore, an approach has been introduced that uses the two-dimensional material as channel layers to replace the silicon. Furthermore, characteristics of the transistor may be improved by adopting a gate all around (GAA) structure. However, the two-dimensional material may have a small thickness and may include surface impurities. Therefore, it is difficult for the transistor including the two-dimensional materials as the channel layer to have desired electrical characteristics.

### SUMMARY

Various example embodiments provide a semiconductor device having excellent electrical characteristics.

Various example embodiments provide a method for manufacturing a semiconductor device having excellent electrical characteristics.

According to some example embodiments, there is provided a semiconductor device including a base layer; a plurality of channel regions spaced apart from an upper surface of the base layer and spaced apart from each other in a vertical direction perpendicular to an upper surface of the base layer, the plurality of channel regions including a two-dimensional material and having p-type conductivity; and a first gate layer and a second gate layer. The first gate layer includes a metal chloride, and contacts and surrounds surfaces of the plurality of channel regions. The second gate layer surrounds a surface of the first gate layer, and includes the same metal element as the metal chloride.

According to some example embodiments, there is provided a semiconductor device including a base layer; a plurality of two-dimensional material patterns spaced apart from an upper surface of the base layer and spaced apart from each other in a vertical direction; a source contact pattern filling a gap between the plurality of two-dimensional material patterns and contacting an upper surface and a lower surface of a first edge of the plurality of two-dimensional material patterns; and a drain contact pattern filling a gap between the plurality of two-dimensional material patterns and contacting an upper surface and a lower surface of a second edge of the plurality of two-dimensional material patterns. A first gate layer including a metal chloride and a second gate layer are disposed on surfaces of the plurality of two-dimensional material patterns, and the metal chloride and the second gate layer include the same metal element. The first edge and the second edge are disposed on opposite sides of the first gate layer in a horizontal direction.

According to some example embodiments, there is provided a semiconductor device including a base layer; a source contact pattern and a drain contact pattern on an upper surface of the base layer; and a plurality of channel regions spaced apart from each other in a vertical direction perpendicular to the upper surface of the base layer. The plurality of channel regions have two end portions in contact with opposing sidewalls of the source contact pattern and the drain contact pattern, include a two-dimensional material, and have p-type conductivity. A first gate layer and a second gate layer are disposed on surfaces of the plurality of channel regions. The source contact pattern and the drain contact pattern are disposed on opposite sides of the plurality of channel regions in a horizontal direction. The first gate layer includes a metal chloride, the second gate layer surrounds a surface of the first gate layer, and the metal chloride and the second gate layer include the same metal element.

According to example embodiments, the semiconductor device includes a first gate layer including a metal chloride contacting channel regions including a two-dimensional material, and p-type conductivity may be induced in the channel regions by the metal chloride. As the channel regions have the p-type conductivity, a transistor in the semiconductor device may have high mobility. In addition, the crystalline quality of the channel regions may be preserved despite the induction of the p-type conductivity. Accordingly, the semiconductor device may have excellent electrical characteristics.

However, the effects of the present invention are not limited to the effects described above, and may be variously expanded within the spirit and scope of the present invention.

### BRIEF DESCRIPTION OF THE DRAWINGS

Various example embodiments will be more clearly understood from the following detailed description taken in conjunction with the accompanying drawings.

FIGS. 1 to 29 represent various non-limiting, example embodiments as described herein.

FIGS. 1 and 2 are a cross-sectional view and a perspective view of a stacked structure in a semiconductor device according to example embodiments;

FIG. 3A is a cross-sectional view of a semiconductor device according to example embodiments;

FIG. 3B is a perspective view of a portion of a semiconductor device according to example embodiments;

FIG. 4 is a cross-sectional view of a semiconductor device according to example embodiments;

FIG. 5 is a cross-sectional view of a semiconductor device according to example embodiments;

FIGS. 6 to 13 are cross-sectional views illustrating a method of manufacturing a semiconductor device according to example embodiments;

FIG. 14A is a cross-sectional view of a semiconductor device according to example embodiments;

FIG. 14B is a perspective view showing a portion of a semiconductor device according to example embodiments;

FIGS. 15 to 21 are cross-sectional views illustrating a method of manufacturing a semiconductor device according to example embodiments;

FIG. 22 is a cross-sectional view of a semiconductor device according to example embodiments; and

FIGS. 23 to 29 are cross-sectional views illustrating a method of manufacturing a semiconductor device according to example embodiments.

### DETAILED DESCRIPTION

Hereinafter, various example embodiments will be described in detail with reference to the accompanying drawings. In the following description, directions perpendicular to each other on the same horizontal plane may be referred to as a first direction and a second direction, and a direction perpendicular to each of the first and second directions may be referred to as a vertical direction.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, 'same' and 'equal' may encompass identicality or near identicality. The term “substantially” may be used herein to emphasize this meaning.

Features described in connection with one example embodiment may be combined with those of other embodiments unless the context clearly indicates otherwise. For example, descriptions of components in one embodiment are equally applicable to other embodiments unless structurally conflicting. Since same or similar reference numerals generally designate same or similar elements, such cross-application would be apparent to those skilled in the art.

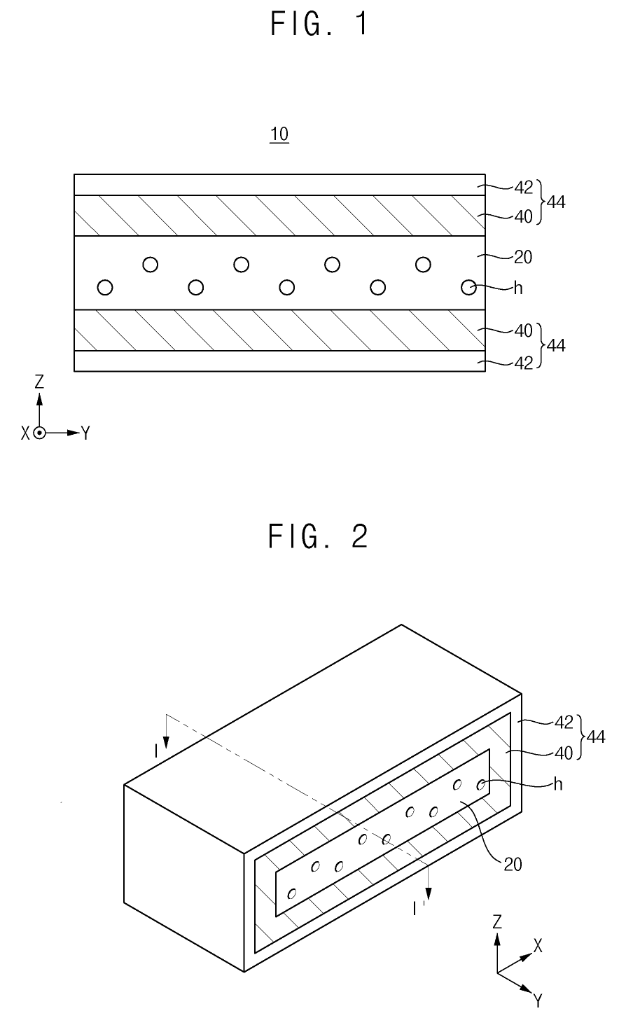

FIGS. 1 and 2 are a cross-sectional view and a perspective view of a stacked structure in a semiconductor device according to example embodiments. For example, FIGS. 1 and 2 show only a portion of a semiconductor device according to example embodiments.

FIG. 1 is a cross-sectional view taken along line I-I’ of FIG. 2.

Referring to FIGS. 1 and 2, a stacked structure 10 may include a channel pattern 20 including two-dimensional material and a gate structure 44 surrounding the channel pattern 20. The stacked structure 10 may serve as a channel and a gate of a P-type transistor.

The two-dimensional material may be formed as a sheet having a nanoscopic thickness. The two-dimensional material may be one or two atoms (or molecules) thick. The material may have crystal structure. The two-dimensional material may exhibit unique electrical, mechanical, and optical properties due to its reduced dimensionality. For example, the two-dimensional material included in the channel pattern 20 may be a material having a thickness of one atomic layer, and may have physical and chemical properties different from the physical and chemical properties of typical three-dimensional materials. The two-dimensional material may include at least one of, for example, graphene, black phosphorus, hexagonal boron nitride (hBN), and transition metal dichalcogenide (TMD). The transition metal dichalcogenide may include, for example, one transition metal selected from Mo, W, Nb, V, Ta, Ti, Zr, Hf, Tc, and Re, and one chalcogen element selected from S, Se, and Te. The transition metal dichalcogenide may be represented, for example, as MX2, where M may be a transition metal and X may be a chalcogen element. Accordingly, the TMD may include, for example, MoS2, MoSe2, MoTe2, WS2, WSe2, WTe2, ZrS2, ZrSe2, HfS2, HfSe2, NbSe2, ReSe2, etc.

In example embodiments, each of the channel patterns 20 may be formed of a single continuous layer or a multilayer.

When a two-dimensional material is partially oxidized, electrons may be lost from the channel pattern 20, creating holes. The created holes may be uniformly arranged in the channel pattern 20. For example, the holes h may be doped in the channel pattern 20. In the present specification, inducing p-type conductivity by generating or increasing holes in the channel pattern 20 may be referred to as the channel pattern 20 being 'doped' with holes. A portion of the two-dimensional material may be oxidized by the metal chloride included in the gate structure 44 contacting the channel pattern 20, so that an electron density in the channel pattern 20 may decrease and a hole density in the channel pattern 20 may increase. Therefore, doping of the holes h in the channel pattern 20 may be induced by the metal chloride. The holes h may be uniformly doped in the channel pattern 20. Further, damage of the channel patterns 20 due to the doping of the holes h may not occur.

The gate structure 44 may surround a surface of the channel pattern 20. The gate structure 44 may surround an upper surface, sidewalls and a lower surface of the channel pattern 20. The gate structure 44 may face the upper surface and the lower surface of the channel pattern 20.

The gate structure 44 may include a first gate layer 40 contacting the surface of the channel pattern 20 and a second gate layer 42 on an entire surface of the first gate layer 40. The first gate layer 40 may include a metal chloride, and the metal chloride may be formed by ionic bonding of metal and chlorine (Cl). Thus, the first gate layer 40 may include the metal and chlorine. The first gate layer 40 may also be referred to as a metal chloride layer. The second gate layer 42 may include a metal oxide.

The metal chloride layer 40 may completely cover the upper surface and the lower surface of the channel pattern 20 and the sidewall in the first direction X of the channel pattern 20. The metal chloride layer 40 may serve as a medium for doping holes h within the channel pattern 20, and may also serve as a portion of the gate structure 44.

The metal chloride layer 40 may include a material having a reduction potential (or may have a Fermi energy level) lower than a valence energy level of a material included in the channel pattern 20.

The metal chloride layer 40 may include, for example, hafnium chloride (HfCl₄), aluminum chloride (AlCl), zirconium chloride (ZrCl), titanium chloride (TiCl), vanadium chloride (VCl₃), niobium chloride (NbCl₅), tantalum chloride (TaCl₅), etc.

The second gate layer 42 may include a metal included in the metal chloride layer 40. For example, the second gate layer 42 may be an oxide of the metal included in the metal chloride layer 40.

The second gate layer 42 may include, for example, hafnium oxide, aluminum oxide, zirconium oxide, titanium oxide, tantalum oxide, or the like.

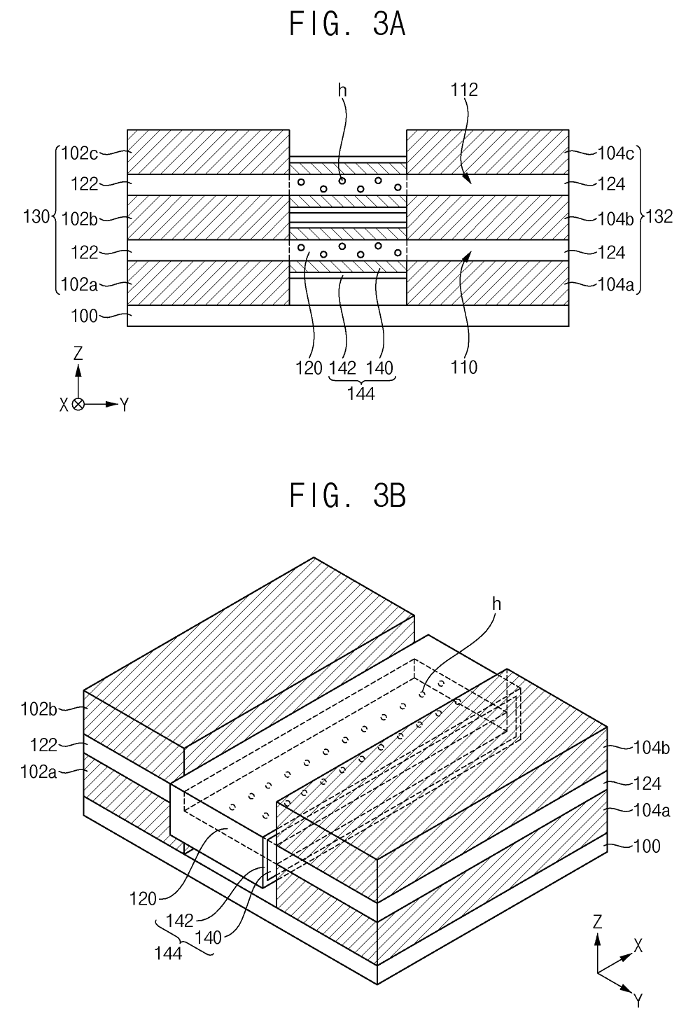

FIG. 3A is a cross-sectional view of a semiconductor device according to example embodiments. FIG. 3B is a perspective view of a portion of a semiconductor device according to example embodiments. For example, FIGS. 1 and 2 may be regarded as enlarged views illustrating a channel pattern and a gate structure of the semiconductor device of FIGS. 3A and 3B. In some example embodiments, FIGS. 3A and 3B illustrate only a portion of a semiconductor device.

FIG. 3B illustrates a lower portion including a lowermost channel pattern in the semiconductor device.

Referring to FIGS. 3A and 3B, the semiconductor device may include a base layer 100, an active structure, and a gate structure 144. The active structure may be an active pattern. The active pattern may include a source contact structure 130, a drain contact structure 132, and channel patterns 120. For example, the channel patterns 120 may be referred to as channel regions.

The base layer 100 may include an insulation material at least on a top portion.

In example embodiments, the base layer 100 may be an insulation layer formed on a substrate. The substrate may include, for example, silicon, germanium, silicon-germanium, or a group III-V compound such as GaP, GaAs, GaSb, etc. For example, the substrate may be a silicon-on-insulator (SOI) substrate or a germanium-on-insulator (GOI) substrate. The base layer 100 may include, for example, silicon nitride, silicon oxynitride, silicon oxycarbide, silicon boron nitride, silicon carbonitride, silicon oxycarbonitride, or a combination thereof. In some example embodiments, the base layer 100 may be an insulation substrate.

Two-dimensional material layer patterns (which may be two-dimensional material patterns) 110 and 112 may be arranged on the base layer 100 to be spaced apart from each other. The two-dimensional material layer patterns 110 and 112 may be provided as a portion of the source contact structure 130, a portion of the drain contact structure 132, and the channel patterns 120. A first level two-dimensional material layer pattern 110 positioned on the first level in the vertical direction and a second level two-dimensional material layer pattern 112 positioned on the second level in the vertical direction are illustrated in FIG. 3A, but this may not be limited thereto. The two-dimensional material layer pattern may be positioned only on the first level, or may be additionally positioned on a third level or higher.

In FIG. 3A, the two-dimensional material layer patterns 110 and 112 positioned on each level are illustrated as having the same vertical thickness, but this may not be limited thereto. For example, at least one of the two-dimensional material layer patterns 110 and 112 positioned on each level may have different vertical thicknesses.

Each of the two-dimensional material layer pattern 110 and 112 may include the channel pattern 120, a first channel connection pattern 122 directly adjacent to or contacting a first end in the second direction Y of the channel pattern 120, and a second channel connection pattern 124 directly adjacent to or contacting a second end, which is the other end of the first end, of the channel pattern 120. For example, the second end may be disposed opposite to the first end. In example embodiments, the semiconductor device may include a plurality of source regions (e.g., the first channel connection patterns 122) and a plurality of drain regions (e.g., the second channel connection patterns 124) disposed on the upper surface of the base layer 100. Each of the source regions may be connected to the first end of a corresponding one of the plurality of channel patterns 120, and each of the drain regions may be connected to the second end of a corresponding one of the plurality of channel patterns 120. In this configuration, each of the first ends may face away from a corresponding one of the second ends.

The first channel connection pattern 122 and the second channel connection pattern 124 may be spaced apart from each other with the channel pattern 120 interposed therebetween. For example, the first channel connection pattern 122 and the second channel connection pattern 124 may be disposed on opposite sides of the channel pattern 120. The channel pattern 120, the first channel connection pattern 122, and the second channel connection pattern 124 may be a single continuous body, so that the channel pattern 120, the first channel connection pattern 122, and the second channel connection pattern 124 may include the same material. Further, the channel pattern 120, the first channel connection pattern 122, and the second channel connection pattern 124 may be continuously formed without an interface. The first channel connection pattern 122 and the second channel connection pattern 124 may be referred to as a source region and a drain region, respectively.

Each of the two-dimensional material layer patterns 110 and 112 may include the same materials as examples of materials of the two-dimensional material layer described with reference to FIG. 1.

The source contact structure 130 and the drain contact structure 132 may be disposed on an upper surface of the base layer 100. The source contact structure 130 may contact the first end portions of a plurality of channel patterns 120. The drain contact structure 132 may contact the second end portions of the plurality of channel patterns 120.

A portion of the source contact structure 130 may fill a gap in the vertical direction Z of a first edge of the two-dimensional material layer patterns 110 and 112, and may contact at least an upper surface and a lower surface of the first edge of the two-dimensional material layer patterns 110 and 112. A portion of the drain contact structure 132 may fill a gap in the vertical direction Z of a second edge opposite the first edge of the two-dimensional material layer patterns 110 and 112, and may contact at least the upper surface and the lower surface of the second edge of the two-dimensional material layer patterns 110 and 112.

The source contact structure 130 may include a plurality of source contact patterns 102a, 102b and 102c spaced apart from each other in the vertical direction Z, and the first channel connection pattern 122 arranged between the source contact patterns 102a, 102b and 102c. The source contact structure 130 may include the source contact patterns 102a, 102b and 102c and the first channel connection patterns 122, which are alternately and repeatedly stacked. The source contact patterns 102a and 102c may be positioned at a lowermost portion and an uppermost portion of the source contact structure 130, respectively. The lowermost source contact pattern 102a may contact the base layer 100.

In the present disclosure, a combination of a plurality of patterns may be collectively described as a single 'pattern.' By way of example, a stack comprising the first to third source contact patterns 102a, 102b, and 102c may be collectively referred to as a 'source contact pattern.'

For example, the source contact structure 130 may have a structure in which a first source contact pattern 102a, a first channel connection pattern 122, a second source contact pattern 102b, a first channel connection pattern 122, and a third source contact pattern 102c are sequentially stacked. In example embodiments, the source contact structure 130 may extend in the first direction X.

In example embodiments, the first to third source contact patterns 102a, 102b and 102c may include platinum (Pt), palladium (Pd), gold (Au), nickel (Ni), ruthenium (Ru), niobium (Nb), iridium (Ir), tungsten (W), molybdenum (Mo), cobalt (Co), scandium (Sc), yttrium (Y), vanadium (V), indium (In), zinc (Zn), or a combination thereof.

The drain contact structure 132 may include a plurality of drain contact patterns 104a, 104b and 104c spaced apart from each other in the vertical direction Z, and the second channel connection pattern 124 disposed between the drain contact patterns 104a, 104b and 104c. The drain contact structure 132 may have a structure in which the drain contact patterns 104a, 104b and 104c and the second channel connection pattern 124 are alternately and repeatedly stacked. The drain contact patterns 104a and 104c may be positioned at a lowermost portion and an uppermost portion of the drain contact structure 132, respectively. The lowermost drain contact pattern 104a may contact the base layer 100. In example embodiments, the drain contact structure 132 may extend in the first direction X.

The drain contact structure 132 may have the same stacked structure as the source contact structure 130. The drain contact structure 132 may face the source contact structure 130 in the second direction Y.

For example, the drain contact structure 132 may have a structure in which a first drain contact pattern 104a, a second channel connection pattern 124, a second drain contact pattern 104b, a second channel connection pattern 124, and a third drain contact pattern 104c are sequentially stacked. A material of the first to third drain contact patterns 104a, 104b and 104c may include a material the same as a material of the first to third source contact patterns 102a, 102b and 102c.

In example embodiments, the first to third source contact patterns 102a, 102b and 102c may be spaced apart from each other with the first channel connection pattern 122 interposed therebetween, so that the first to third source contact patterns 102a, 102b and 102c may be physically separated from each other. In example embodiments, outer sidewalls of the first to third source contact patterns 102a, 102b and 102c and outer sidewalls of the first channel connection patterns 122 may be aligned in the vertical direction Z with each other.

In example embodiments, the first to third drain contact patterns 104a, 104b and 104c may be spaced apart from each other with the second channel connection pattern 124 interposed therebetween, so that the first to third drain contact patterns 104a, 104b and 104c may be physically separated from each other. In example embodiments, outer sidewalls of the first to third drain patterns 104a, 104b and 104c and outer sidewalls of the second channel connection patterns 124 may be aligned in the vertical direction Z with each other.

The channel patterns 120 may be arranged to be spaced apart from each other in the vertical direction Z. A lowermost channel pattern 120 may be spaced apart from the base layer 100. The channel patterns 120 may be disposed between the source contact structure 130 and the drain contact structure 132 in the second direction Y. Each of the channel patterns 120 may have a bridge shape that connects one end in the second direction Y of the first channel connection pattern 122 and one end in the second direction Y of the second channel connection pattern 124.

Holes h may be arranged within the two-dimensional material included in the channel pattern 120, and the holes may be generated from partial oxidation of the two-dimensional material by the first gate layer 140 of the gate structure 144. For example, the channel patterns 120 may be doped with holes h. Particularly, a portion of the channel patterns 120 may be oxidized by the metal chloride of the gate structure 144 contacting the channel patterns 120, and thus an electron density within the channel pattern 120 may be decreased and a hole density within the channel pattern 120 may be increased. Therefore, the same effect as when the holes h are doped into the channel patterns 120 may be achieved by forming of the metal chloride. The holes h may be uniformly arranged within the channel patterns 120. Further, the channel patterns 120 may not be damaged by doping of the holes h.

In some embodiments, the channel pattern 120 having p-type conductivity may refer to a state in which holes are generated as majority carriers. Specifically, in some embodiments, this p-type conductivity is induced by a surface charge transfer mechanism where the first gate layer 140 (e.g., metal chloride layer) extracts electrons from the channel pattern 120, rather than by substitutional doping that replaces atoms within the lattice of the two-dimensional material.

The first channel connection patterns 122 and second channel connection patterns 124 included in the source contact structure 130 and drain contact structure 132 may not be doped with the holes.

The gate structure 144 may surround the surface of each of the channel patterns 120. The gate structures 144 surrounding the channel patterns 120 may be spaced apart from each other in the vertical direction Z. The adjacent gate structures 144 may be spaced apart from each other in the vertical direction Z in a cross-sectional view. For example, gaps between adjacent gate structures 144 in the vertical direction Z may be provided. Accordingly, the number of gate structures 144 may be the same as the number of the channel patterns 120. Each of the gate structures 144 may surround an entire surface of each of the channel patterns 120. Each of gate structures 144 may contact or face sidewalls of the source contact structure 130 and the drain contact structure 132. Each of gate structures 144 may face an upper surface, a sidewall and a lower surface of the channel pattern 120. The gate structure 144 may include a first gate layer 140 including the metal chloride and a second gate layer 142 including the metal oxide.

The metal chloride included in the first gate layer 140 of the gate structure 144 may be the same as the metal chloride layer described in the stacked structure of FIG. 1. The metal oxide included in the second gate layer 142 of the gate structure 144 may be the same as the metal oxide described in the stacked structure of FIG. 1. In some embodiments, the metal chloride (e.g., HfCl₄) and the second gate layer (e.g., Hf oxide) 142 may include the same metal element (e.g., Hf).

In example embodiments, an insulation material may fill a gap between the gate structures 144 in the vertical direction Z and a gap between a lowermost gate structure 144 and the base layer 100, within a region between the source contact structure 130 and the drain contact structure 132 in the second direction. In some example embodiments, the gap between the gate structures 144 in the vertical direction Z and the gap between the lowermost gate structure 144 and the base layer 100 may be an air gap filled with air, within the region between the source contact structure 130 and the drain contact structure 132 in the second direction Y. It should be appreciated that an “air gap” may comprise a gap having air or other gases (e.g., such as those present during manufacturing) or may comprise a gap forming a vacuum therein.

Similarly, for each of the embodiments described below, the gap between the gate structures 144 in the vertical direction Z, and the gap between the lowermost gate structure 144 and the base layer 100 may be filled with an insulation material or air, within the range between the source contact structure 130 and the drain contact structure 132 in the second direction Y.

The transistor may be a P-type transistor. The transistor may have channel patterns 120 including a two-dimensional material, and in this case, mobility of charges in the transistor may be reduced due to a contamination and defects in the channel patterns 120 or high junction resistance. However, according to an example embodiment, the first gate layer 140 including the metal chloride may contact the channel patterns 120. A portion of the channel patterns 120 may be oxidized by the metal chloride, so that a plurality of holes may be doped within each of the channel patterns 120. Therefore, the transistor may have high mobility. In addition, the channel patterns 120 of the transistor may not be damaged due to doping of holes.

In some embodiments, due to the surface adsorption and charge transfer interaction described above, a concentration profile of chlorine (Cl) in a depth direction of the device may exhibit a peak at an interface between the channel pattern 120 and the first gate layer 140. Accordingly, a concentration of chlorine at the interface may be greater than a concentration of chlorine inside the channel pattern 120 (e.g., in a bulk region of the channel pattern).

As used herein, a semiconductor device may refer, for example, to a device such as a bare semiconductor chip (e.g., a memory chip and/or a logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through-substrate vias, or other electrical connection elements, and may include memory devices such as volatile or non-volatile memory devices. A semiconductor package may include a package substrate, one or more semiconductor chips, and an encapsulant formed on the package substrate and covering the semiconductor chips. Additionally, such a semiconductor chip may be a semiconductor device singulated from a wafer (which may be formed with a base substrate, such as a bulk silicon substrate, a bulk germanium substrate, or a silicon-on-insulator (SOI) substrate). For example, in example embodiments, the transistor described herein may be integrated into a larger electronic circuit or system, such as a logic device. For example, when the transistor is utilized within a logic circuit, the gate structure (e.g., the electrode layer 320) may be electrically connected to an input signal line or a local interconnect. Furthermore, the source contact structure (e.g., 130 or 230) and the drain contact structure (e.g., 132 or 232) may be electrically connected to a power rail (e.g., a VDD line or a VSS line), an output signal line, or other interconnects via metal routing lines to form various logic gates (e.g., inverters, NAND gates, or NOR gates).

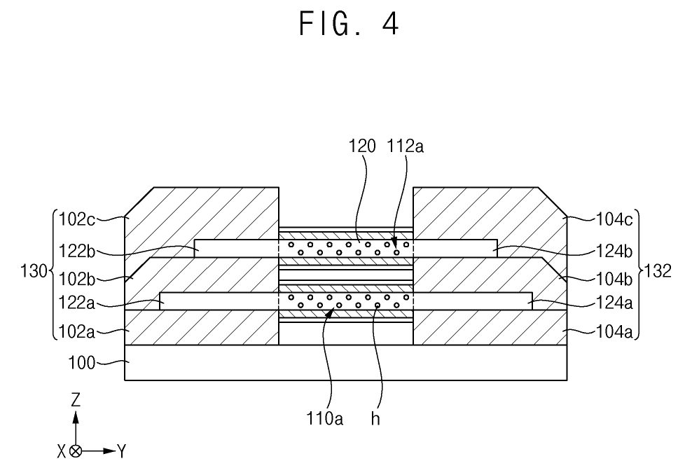

FIG. 4 is a cross-sectional view of a semiconductor device according to example embodiments.

The semiconductor device shown in FIG. 4 may be the same as the semiconductor device described with reference to FIGS. 3A and 3B, except for lengths of a first level 2D material layer and a second level 2D material layer, a shape of a source contact structure and a shape of a drain contact structure. Therefore, a description of the same portions may be omitted.

Referring to FIG. 4, the source contact structure 130 may include a first contact pattern 102a, a second contact pattern 102b and a third source contact pattern 102c and first channel connection patterns 122a and 122b. The first channel connection patterns 122a and 122b may be interposed between the first source contact pattern 102a and the second source contact pattern 102b and between the second source contact pattern 102b and the third source contact pattern 102c, respectively. Outer edge portions of upper surfaces and lower surfaces of the first source contact pattern 102a, the second source contact pattern 102b and the third source contact pattern 102c may contact each other.

The drain contact structure 132 may include a first drain contact pattern 104a, a second drain contact pattern 104b and a third drain contact pattern 104c, and second channel connection patterns 124a and 124b. The second channel connection patterns 124a and 124b may be interposed between the first drain contact pattern 104a and the second drain contact pattern 104b and between the second drain contact pattern 104b and the third drain contact pattern 104c, respectively. Outer edges of each of upper surfaces and lower surfaces of the first drain contact pattern 104a, the second drain contact pattern 104b, and the third drain contact pattern 104c may contact each other.

A length in the second direction Y of the two-dimensional material layer pattern 112a positioned on an upper level may be less than a length in the second direction Y of the two-dimensional material layer pattern 110a positioned on a lower level. A length in the second direction Y of the first channel connection pattern 122b positioned on an upper level may be less than a length in the second direction Y of the first channel connection pattern 122a positioned on the lower level. In example embodiments, the lengths in the second direction Y of the first channel connection patterns 122a and 122b may gradually decrease from a lower portion to an upper portion thereof. The length in the second direction Y of the second channel connection pattern 124b positioned on the upper level may be less than the length in the second direction Y of the second channel connection pattern 124a positioned on the lower level. In example embodiments, the lengths in the second direction Y of the second channel connection patterns 124a and 124b may gradually decrease from the lower level to the upper level. However, the lengths in the second direction Y of the channel patterns 120 positioned on each vertical level may be the same.

The gate structure formed on the channel patterns 120 may be the same as that described with reference to FIGS. 3A and 3B.

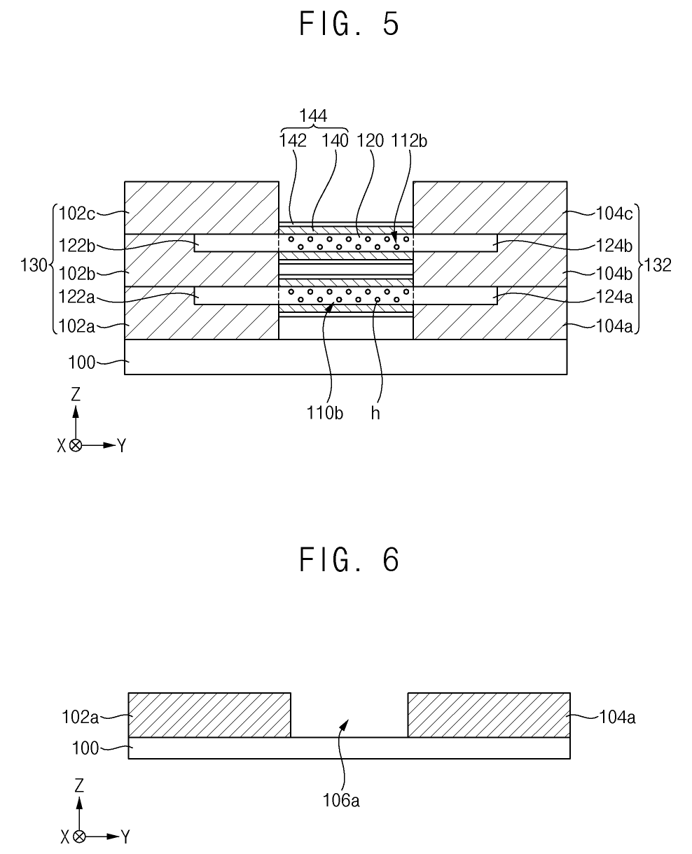

FIG. 5 is a cross-sectional view of a semiconductor device according to example embodiments.

The semiconductor device shown in FIG. 5 may be the same as the semiconductor device described with reference to FIGS. 3A and 3B, except for the shapes of the source contact structure and the drain contact structure. Therefore, a description of the same portions may be omitted.

Referring to FIG. 5, the source contact structure 130 may include a first source contact pattern 102a, a second source contact pattern 102b, a third source contact pattern 102c, and first channel connection patterns 122a and 122b. The first channel connection patterns 122a and 122b may be interposed between the first source contact pattern 102a and the second source contact pattern 102b and between the second source contact pattern 102b and the third source contact pattern 102c, respectively. Outer edges of upper and lower surfaces of the first source contact pattern 102a, the second source contact pattern 102b, and the third source contact pattern 102c may contact each other.

An outer edge of the upper surface of each of the first and second source contact patterns 102a and 102b may include a protrusion protruding upward. Therefore, each of the first and second source contact patterns 102a and 102b may include a first upper surface having a flat surface and a second upper surface protruding from the flat surface. The first channel connection pattern 122a and 122b may be disposed on the first upper surfaces of the first and second source contact patterns 102a and 102b, and may contact the first upper surfaces of the first and second source contact patterns 102a and 102b. In addition, the second upper surface of the first source contact pattern 102a may contact a bottom surface of the second source contact pattern 102b. In example embodiments, the upper surface of the first channel connection pattern 122a on the first level may be coplanar with the second upper surface of the first source contact pattern 102a. In example embodiments, the upper surface of the first channel connection pattern 122b on the second level may be coplanar with the second upper surface of the second source contact pattern 102b. The upper surface of the third source contact pattern 102c on an uppermost level may not include the protrusion.

The drain contact structure 132 may include a first drain contact pattern 104a, a second drain contact pattern 104b, a third drain contact pattern 104c and second channel connection patterns 124a and 124b. The second channel connection patterns 124a and 124b may be interposed between the first drain contact pattern 104a and the second drain contact pattern 104b and between the second drain contact pattern 104b and the third drain contact pattern 104c, respectively. Outer edges of upper and lower surfaces of the first drain contact pattern 104a, the second drain contact pattern 104b, and the third drain contact pattern 104c may contact each other. The outer edge of the upper surface of the first and second drain contact patterns 104a and 104b may include protrusions protruding upward. Therefore, the first and second drain contact patterns 104a and 104b may include a third upper surface having a flat surface and a fourth upper surface protruding from the flat surface. The second channel connection patterns 124a and 124b may be disposed on the third upper surface of the first and second drain contact patterns 104a and 104b, and may contact the third upper surfaces of the first and second drain contact patterns 104a and 104b. The fourth upper surface of the first drain contact pattern 104a may contact a bottom surface of the second drain contact pattern 104b. In example embodiments, the upper surface of the second channel connection pattern 124a on the first level may be coplanar with the fourth upper surface of the first drain contact pattern 104a. In example embodiments, the upper surface of the second channel connection pattern 124b on the second level may be coplanar with the fourth upper surface of the second drain contact pattern 104b. The upper surface of the third drain contact pattern 104c on the uppermost level may not include the protrusion.

The gate structure formed on the channel patterns may be substantially the same as that described with reference to FIGS. 3A and 3B.

FIGS. 6 to 13 are cross-sectional views illustrating a method of manufacturing a semiconductor device according to example embodiments.

Referring to FIG. 6, a base layer 100 including an insulation material may be provided. In example embodiments, the base layer 100 may be formed on a substrate. In example embodiments, the base layer 100 may be an insulating substrate.

A first metal layer may be formed on the base layer 100. The first metal layer may include, e.g., platinum (Pt), palladium (Pd), gold (Au), nickel (Ni), ruthenium (Ru), niobium (Nb), iridium (Ir), tungsten (W), molybdenum (Mo), cobalt (Co), scandium (Sc), yttrium (Y), vanadium (V), indium (In), zinc (Zn), or a combination thereof. The first metal layer may include a metal having a high work function such as palladium (Pd), ruthenium (Ru), gold (Au), nickel (Ni), platinum (Pt), or the like.

The first metal layer may be patterned to form a first trench 106a extending in the first direction X and exposing an upper surface of the base layer 100. The patterning process may include an etching process. As the first trench 106a is formed, the first metal layer may be transformed into a first source contact pattern 102a and a first drain contact pattern 104a, which are spaced apart from each other and facing each other in the second direction Y.

In some example embodiments, a first recess may be formed in the first source contact pattern 102a and the first drain contact pattern 104a so that outer edges of the first source contact pattern 102a and the first drain contact pattern 104a may protrude, in the patterning process of the first metal layer. In this case, the semiconductor device shown in FIG. 5 may be manufactured by subsequent processes.

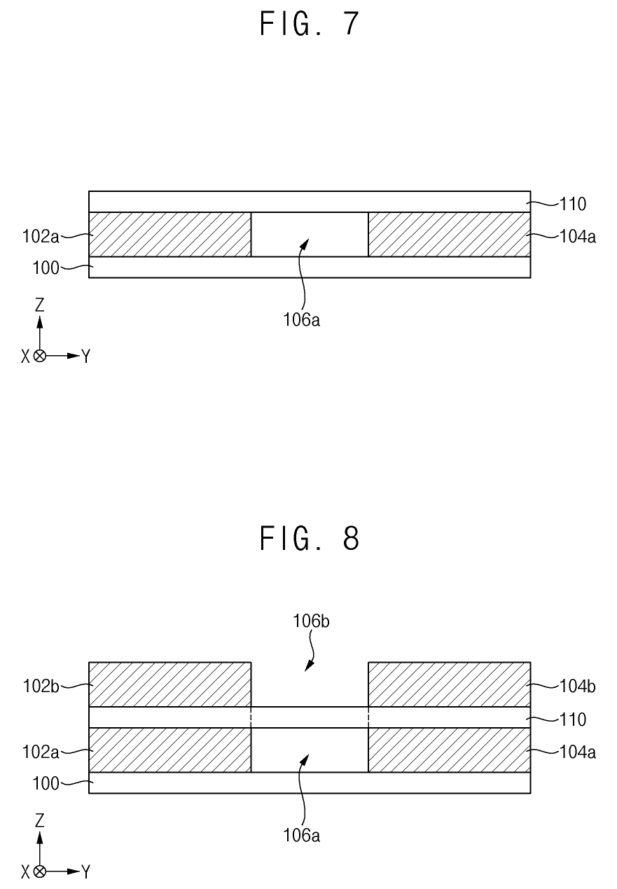

Referring to FIG. 7, a first level two-dimensional material layer pattern 110 may be formed to cover the upper surface of the first source contact pattern 102a and the upper surface of the first drain contact pattern 104a, and may be also formed over the first trench 106a between the first source contact pattern 102a and the first drain contact pattern 104a. The first level two-dimensional material layer pattern 110 may contact the upper surface of the first source contact pattern 102a and the upper surface of the first drain contact pattern 104a. A space of the first trench 106a may remain below a bottom surface of the first level two-dimensional material layer pattern 110 disposed between the first source contact pattern 102a and the first drain contact pattern 104a. For example, the first level two-dimensional material layer pattern 110 may not fill the first trench 106a. The first level two-dimensional material layer pattern 110 may cover an entrance of the first trench 106a.

The first level two-dimensional material layer pattern 110 may include, for example, graphene, carbon nanotubes, transition metal dichalcogenides (TMDs), or a combination thereof.

The first level two-dimensional material layer pattern 110 may be formed by using various methods. The first level two-dimensional material layer pattern 110 may be formed by using, for example, a top-down method such as a mechanical exfoliation, a liquid solution exfoliation, or an electrochemical exfoliation, or a bottom-up method such as a chemical vapor deposition (CVD), a molecular beam epitaxy (MBE), or an atomic layer deposition (ALD). The first level two-dimensional material layer pattern 110 may be transferred to a target location by using various methods. The first level two-dimensional material layer pattern 110 may be transferred by using, for example, a wet transfer method such as a PMMA-assisted transfer method or a bubble transfer method, a dry transfer method such as a PDMS-based direct dry transfer method or a stamp transfer method, a roll-to-roll transfer method suitable for large-area processes, or a pick-and-place method capable of precise placement. The transfer methods may be selected depending on the target application, required interface quality, and production scale.

In some example embodiments, the first level two-dimensional material layer pattern 110 may be formed to cover a portion of the upper surface of the first source contact pattern 102a and a portion of the upper surface of the first drain contact pattern 104a. The first level two-dimensional material layer pattern 110 may expose an edge in the second direction Y of the upper surface of the first source contact pattern 102a and an edge in the second direction Y of the upper surface of the first drain contact pattern 104a. In this case, the semiconductor device shown in FIG. 4 may be manufactured by subsequent processes.

Referring to FIG. 8, a second metal layer may be formed on the first level two-dimensional material layer pattern 110.

The second metal layer may include, for example, platinum (Pt), palladium (Pd), gold (Au), nickel (Ni), ruthenium (Ru), niobium (Nb), iridium (Ir), tungsten (W), molybdenum (Mo), cobalt (Co), scandium (Sc), yttrium (Y), vanadium (V), indium (In), zinc (Zn), or a combination thereof. In example embodiments, the second metal layer may include a material the same as a material of the first metal layer.

The second metal layer may be patterned to form a second trench 106b extending in the first direction X and exposing the upper surface of the first level two-dimensional material layer pattern 110. As the second trench 106b is formed, the second metal layer may be transformed into a second source contact pattern 102b and a second drain contact pattern 104b spaced apart from each other and facing each other in the second direction Y.

In example embodiments, the second source contact pattern 102b may face the upper surface of the first source contact pattern 102a, and may be disposed on the first edge of the upper surface of the first level two-dimensional material layer pattern 110. In example embodiments, the second drain contact pattern 104b may face the upper surface of the second drain contact pattern 104b, and may be disposed on the second edge of the upper surface of the first level two-dimensional material layer pattern 110. The first and second trenches 106a and 106b may face each other in the vertical direction Z with the first level two-dimensional material pattern 110 interposed therebetween. For example, the first and second trenches 106a and 106b may overlap each other in the vertical direction Z.

In some example embodiments, a second recess may be formed in the second source contact pattern 102b and the second drain contact pattern 104b so that outer edges of the second source contact pattern 102b and the second drain contact pattern 104b may protrude, in the patterning process of the second metal layer. In this case, the semiconductor device shown in FIG. 5 may be manufactured by subsequent processes.

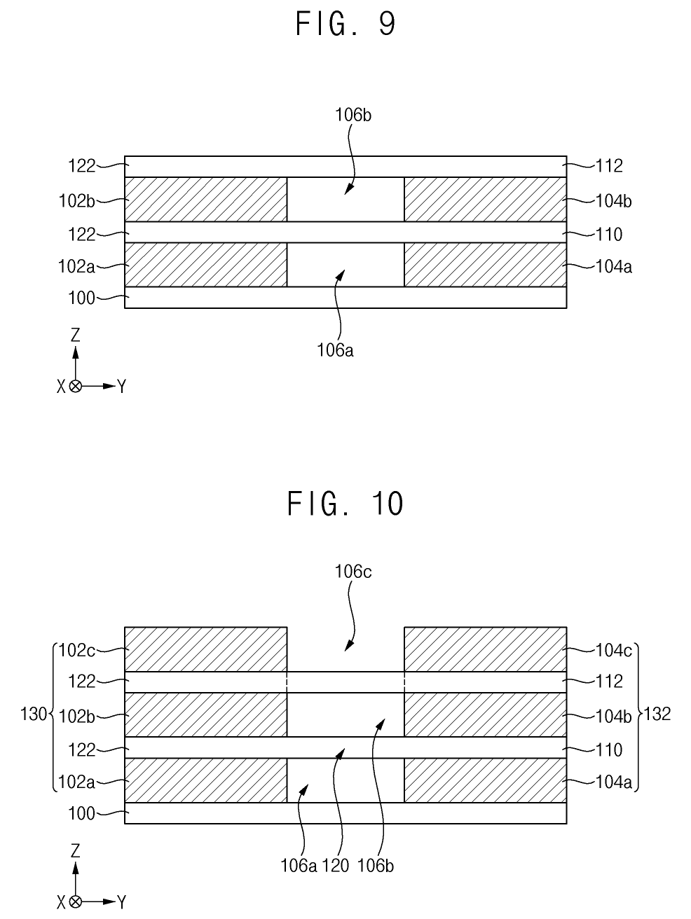

Referring to FIG. 9, a second level two-dimensional material layer pattern 112 may be formed to cover the upper surface of the second source contact pattern 102b and the upper surface of the second drain contact pattern 104b, and may be also formed over the second trench 106b between the upper surface of the second source contact pattern 102b and the second drain contact pattern 104b. The second level two-dimensional material layer pattern 112 may contact the upper surface of the second source contact pattern 102b and the upper surface of the second drain contact pattern 104b. A space of the second trench 106b may remain below a bottom surface of the second level two-dimensional material layer pattern 112 disposed between the second source contact pattern 102b and the second drain contact pattern 104b. The second level two-dimensional material layer pattern 112 may not fill the second trench 106b.

The second level two-dimensional material layer pattern 112 may include, for example, graphene, carbon nanotubes, transition metal dichalcogenides (TMDs), or a combination thereof. In example embodiments, the second level two-dimensional material layer pattern 112 may include the same material as a material of the first level two-dimensional material layer pattern 110.

The second level two-dimensional material layer pattern 112 may be manufactured in a similar manner to the first level two-dimensional material layer pattern 110, and may be transferred to a target location.

In some example embodiments, the second level two-dimensional material layer pattern 112 may be formed to cover a portion of the upper surface of the second source contact pattern 102b and a portion of the upper surface of the second drain contact pattern 104b. The second level two-dimensional material layer pattern 112 may expose the edge in the second direction Y of the upper surface of the second source contact pattern 102b and the edge in the second direction Y of the upper surface of the second drain contact pattern 104b. In this case, the semiconductor device shown in FIG. 4 may be manufactured by subsequent processes.

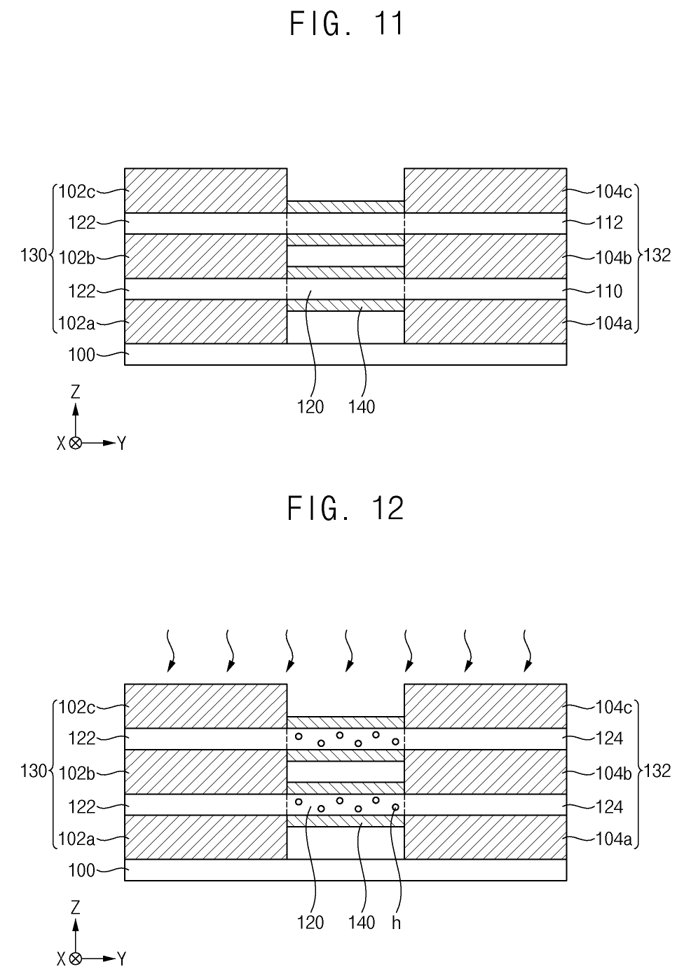

Referring to FIG. 10, a third metal layer may be formed on the second source contact pattern 102b, the second level two-dimensional material layer pattern 112 and the second drain contact pattern 104b. The third metal layer may be patterned to form a third trench 106c extending in the first direction X and exposing the upper surface of the second level two-dimensional material layer pattern 112. As the third trench 106c is formed, the third metal layer may be transformed into a third source contact pattern 102c and a third drain contact pattern 104c, which are spaced apart from each other in the second direction Y and face each other.

Although the example embodiment is described as forming two two-dimensional material layer patterns 110 and 112, three source contact patterns 102a, 102b and 102c and three drain contact patterns 104a, 104b and 104c, the present invention is not limited thereto. For example, a single two-dimensional material layer pattern or three or more two-dimensional material layer patterns may be formed.

In each of the two-dimensional material layer patterns 110 and 112, the portions not covered by the first to third source contact patterns 102a, 102b and 102c and the first to third drain contact patterns 104a, 104b and 104c may be provided as channel patterns 120. In each of the two-dimensional material layer patterns 110 and 112, a portion in contact with the first to third source contact patterns 102a, 102b and 102c may be referred to as a first channel connection pattern 122. In each of the two-dimensional material layer patterns 110 and 112, a portion in contact with the first to third drain contact patterns 104a, 104b and 104c may be referred to as a second channel connection pattern 124. For example, each of the two-dimensional material layer patterns 110 and 112 may include the first channel connection pattern 122, the channel pattern 120, and the second channel connection pattern 124. The first channel connection pattern 122 may be arranged between the first and second source contact patterns 102a and 102b and between the second and third source contact patterns 102b and 102c. A stacked structure of the first to third source contact patterns 102a, 102b and 102c and the first channel connection patterns 122 arranged therebetween is referred to as a source contact structure 130.

The second channel connection patterns 124 may be arranged between the first and second drain contact patterns 104a and 104b and between the second and third drain contact patterns 104b and 104c. The first to third drain contact patterns 104a, 104b and 104c and the second channel connection patterns 124 arranged therebetween are referred to as a drain contact structure 132.

Referring to FIG. 11, a first gate layer 140 may be formed to surround the outer surface of the channel pattern 120. The first gate layer 140 may include a material for doping holes in the channel pattern 120. The first gate layer 140 may include a metal chloride. After the first gate layer 140 is formed, a space may remain between the channel patterns 120 in the vertical direction Z.

The first gate layer 140 may include a material having a reduction potential lower than a valence energy level of the channel pattern 120. The first gate layer 140 may include, for example, hafnium chloride (HfCl₄), aluminum chloride (AlCl), zirconium chloride (ZrCl), titanium chloride (TiCl), vanadium chloride (VCl₃), niobium chloride (NbCl₅), tantalum chloride (TaCl₅), etc.

In example embodiments, the first gate layer 140 may be formed by, e.g., a gas phase doping process, a thermal evaporation process, an E-beam evaporation process, a chemical vapor deposition (CVD) process, an atomic layer deposition (ALD) process, a molecular layer deposition (MLD) process, or physical vapor deposition (PVD) process.

In example embodiments, the first gate layer 140 may be formed by a selective deposition process so that the first gate layer 140 may be deposited only on an outer surface of the channel pattern 120.

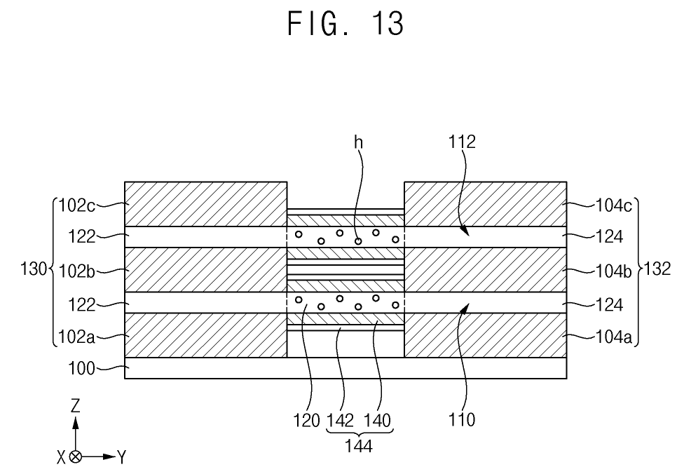

Referring to FIG. 12, a heat treatment process may be performed on the first gate layer 140. At least a portion of each channel pattern 120 may be oxidized by the heat treatment process of the first gate layer 140. Therefore, holes h may be doped within the channel patterns 120.

Since the first gate layer 140 has a reduction potential lower than the valence energy of the channel pattern 120, metal ions of the first gate layer 140 may tend to gain electrons and be reduced when combined with chlorine. Therefore, each of channel patterns 120 may lose electrons, and thus surfaces of the channel patterns 120 may be oxidized. When electrons escape from the channel pattern 120, holes h, which are positively charged spaces (or vacancies), may be created in that location. Therefore, the channel pattern 120 may be considered to be doped with holes h.

In this way, since the doping the holes h in the channel pattern 120 does not use a process such as plasma process or ion implantation process, damage to the channel patterns 120 during the doping process may be reduced.

In example embodiments, the process for forming the first gate layer 140 and the process for doping the holes h may be performed in situ.

Referring to FIG. 13, a second gate layer 142 may be formed on a surface of the first gate layer 140. Even after the second gate layer 142 is formed, a space may remain between the channel patterns 120 in the vertical direction Z. The second gate layer 142 may include a metal included in the metal chloride layer of the first gate layer 140. For example, the second gate layer 142 may be an oxide of the metal material included in the metal chloride layer.

The metal oxide included in the second gate layer 142 may include, for example, hafnium oxide, aluminum oxide, zirconium oxide, titanium oxide, tantalum oxide, and the like.

In example embodiments, the second gate layer 142 may be formed by a selective deposition process so that the second gate layer 142 may be deposited only on the surface of the first gate layer 140.

In some example embodiments, the first and second gate layers 140 and 142 may be formed after forming a mask pattern covering the upper surfaces of the source contact structure 130 and the drain contact structure 132. In this case, the first gate layer 140 and the second gate layer 142 may also be formed on the mask pattern. In this case, the first and second gate layers 140, 142 positioned on the source contact structure 130 and the drain contact structure 132 may be lifted off and removed by removing the mask pattern.

By performing the above processes, holes may be doped within the channel patterns including the two-dimensional material, and a P-type transistor having a gate all-around structure may be manufactured.

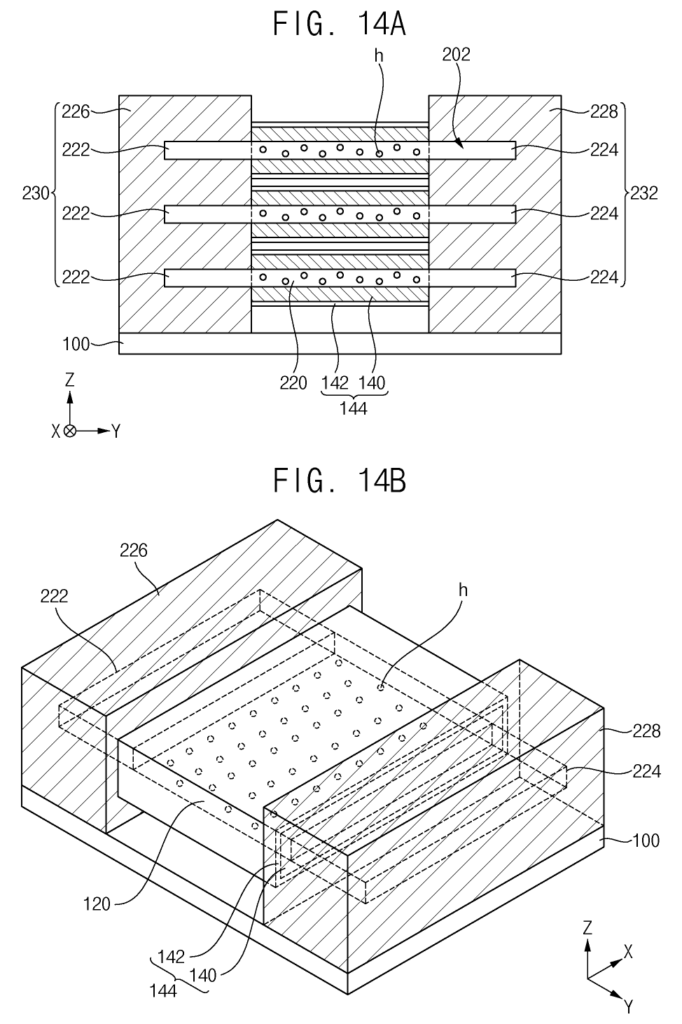

FIG. 14A is a cross-sectional view of a semiconductor device according to example embodiments. FIG. 14B is a perspective view showing a portion of a semiconductor device according to example embodiments.

FIG. 14B illustrates a lower portion of the semiconductor device including a lowermost channel pattern.

Referring to FIGS. 14A and 14B, the semiconductor device may include a base layer 100, a source contact structure 230, a drain contact structure 232, a channel pattern 220, and a gate structure 144.

The base layer 100 may include an insulation material. In example embodiments, the base layer 100 may be an insulation layer formed on a substrate. In some example embodiments, the base layer 100 may be an insulating substrate.

Two-dimensional material layer patterns 202 may be arranged on the base layer 100 to be spaced apart from each other in the vertical direction Z. Each two-dimensional material layer pattern 202 may include a channel pattern 220 and a first channel connection pattern 222 and a second channel connection pattern 224 respectively positioned at opposite ends of the channel pattern 220. The channel pattern 220, the first channel connection pattern 222, and the second channel connection pattern 224 may form a single continuous body, and may include the same material. Furthermore, the channel pattern 220, the first channel connection pattern 222, and the second channel connection pattern 224 may be continuously formed without an interface.

The two-dimensional material layer pattern 202 may include, for example, at least one of graphene, black phosphorus, hBN (hexagonal boron nitride), and a transition metal dichalcogenide (TMD).

The source contact structure 230 may be formed on the base layer 100. The source contact structure 230 may include the first channel connection patterns 222 and a source contact pattern 226. The source contact pattern 226 may fill gaps between the first channel connection patterns 222 being spaced apart from each other, and may cover upper surfaces, lower surfaces, and sidewalls of the first channel connection patterns 222. The source contact pattern 226 may contact surfaces of the plurality of first channel connection patterns 222. The source contact pattern 226 may be connected in the vertical direction Z on the sidewalls of the plurality of first channel connection patterns 222. The source contact pattern 226 may include a metal.

The drain contact structure 232 may be formed on the base layer 100. The drain contact structure 232 may include second channel connection patterns 224 and a drain contact pattern 228. The drain contact pattern 228 may fill gaps between the second channel connection patterns 224 being spaced apart from each other, and may cover upper surfaces, lower surfaces, and sidewalls of the second channel connection patterns 224. The drain contact pattern 228 may contact surfaces of the plurality of second channel connection patterns 224. The drain contact pattern 228 may be connected in the vertical direction Z on the sidewalls of the plurality of second channel connection patterns 224. The drain contact pattern 228 and the source contact pattern 226 may be formed together by the same process. Therefore, the drain contact pattern 228 and the source contact pattern 226 may include the same metal. For example, each of the drain contact pattern 228 and the source contact pattern 226 may be a single continuous body.

The source contact structure 230 and the drain contact structure 232 may be spaced apart from each other in the second direction Y. The source contact structure 230 and the drain contact structure 232 may be arranged to face each other in the second direction Y.

The channel patterns 220 may be arranged between the source contact structure 230 and the drain contact structure 232, and may be spaced apart from each other in the vertical direction Z. Holes h may be doped within the channel patterns 220. The holes h doped within the channel patterns 220 may be formed by the metal chloride of the gate structure 144. The holes h may be uniformly doped within the channel patterns 220. Furthermore, defects of the channel patterns 220 due to the doping of the holes h may not occur.

The gate structure 144 may surround the surface of each of the channel patterns 220. The gate structures 144 surrounding the channel patterns 220 may be spaced apart from each other in the vertical direction Z. Each of the gate structures 144 may face an upper surface and a lower surface of one of the channel patterns 220.

The gate structure 144 may include a first gate layer 140 including the metal chloride and a second gate layer 142 including the metal oxide. In some embodiments, in a vertical cross-sectional view, the gate structure 144 may include a plurality of portions respectively surrounding the plurality of channel patterns 220, and the plurality of portions may be spaced apart from each other in the vertical direction.

The metal chloride included in the first gate layer 140 may be the same as the metal chloride layer described in the stacked structure of FIG. 1. The metal oxide included in the second gate layer 142 may be the same as the metal oxide described in the stacked structure of FIG. 1.

The transistor may be a p-type transistor. The channel patterns may be doped with holes, and thus the transistor may have excellent mobility. Additionally, the channel pattern of the transistor may have no defect due to, e.g., plasma damage.

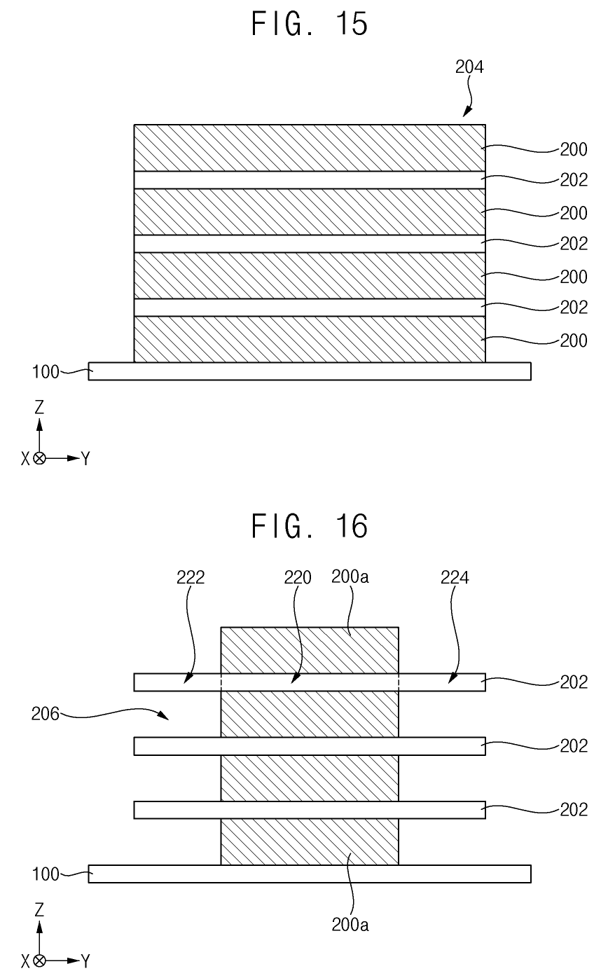

FIG. 15 to 21 are cross-sectional views illustrating a method of manufacturing a semiconductor device according to example embodiments.

Referring to FIG. 15, a base layer 100 including an insulation material may be provided.

A sacrificial layer and a two-dimensional material layer may be alternately and repeatedly stacked on the base layer 100. The sacrificial layer may include a material having an etch selectivity with respect to the two-dimensional material layer. The sacrificial layer may include a metal oxide having a high dielectric constant. Examples of the sacrificial layer include aluminum oxide, hafnium oxide, titanium oxide, zirconium oxide, and the like.

Thereafter, the sacrificial layers and the two-dimensional material layers may be patterned to form a first structure 204 in which a preliminary sacrificial layer pattern 200 and a two-dimensional material layer pattern 202 are alternately and repeatedly stacked on the base layer 100. The first structure 204 may extend in the first direction X. The preliminary sacrificial layer patterns 200 may be positioned at lowermost and uppermost portions of the first structure 204, respectively.

The two-dimensional material layer pattern 202 may be provided as a channel structure through subsequent processes, and a portion where the preliminary sacrificial layer pattern 200 is formed may correspond to a portion between the channel structures in the vertical direction Z. For example, a gate structure may be formed in the portion where the preliminary sacrificial layer pattern 200 is formed through subsequent processes. In example embodiments, each of the preliminary sacrificial layer patterns 200 may have a thickness greater than a thickness of each of the two-dimensional material layer patterns 202.

Referring to FIG. 16, the preliminary sacrificial layer patterns 200 may be etched laterally from sidewalls of the preliminary sacrificial layer patterns 200 to form sacrificial layer patterns 200a. Accordingly, the two-dimensional material layer pattern 202 may protrude laterally further than the sacrificial layer pattern 200a. In addition, a recess 206 defined by upper and lower surfaces of the neighboring two-dimensional material layer patterns 202 and a sidewall of the sacrificial layer pattern 200a may be formed by the etching process. The recess 206 may correspond to a space in the vertical direction Z between the upper and lower surfaces of edges of the neighboring two-dimensional material layer pattern 202. The surface of the edges of the two-dimensional material layer patterns 202 may be exposed by the recesses 206.

In the two-dimensional material layer pattern 202, a portion covered by the sacrificial layer patterns 200a may correspond to the channel pattern 220. In the two-dimensional material layer pattern 202, a portion not covered by the sacrificial layer patterns 200a may correspond to the first channel connection pattern 222 and the second channel connection pattern 224. The two-dimensional material layer pattern 202 may include the channel pattern 220, and the first channel connection pattern 222 and the second channel connection pattern 224 respectively disposed at both ends (or opposite ends) of the channel pattern 220.

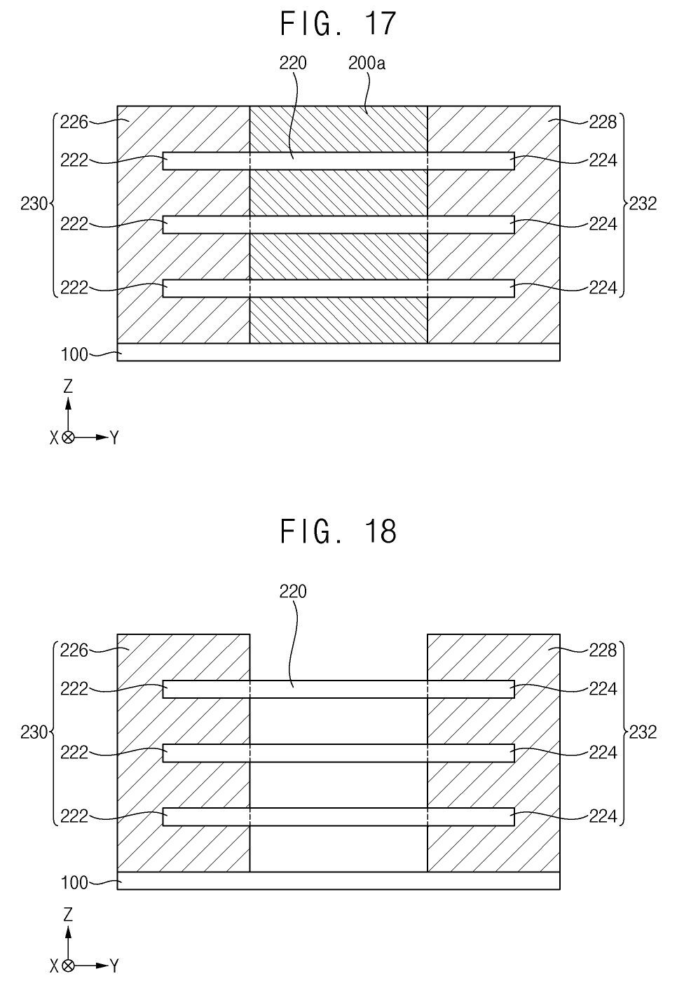

Referring to FIG. 17, a metal layer may be formed on the base layer 100, the sidewalls of the sacrificial layer patterns 200a, and the surfaces of the two-dimensional material layer patterns 202 to fill the recesses 206. The metal layer may be planarized until the upper surface of the uppermost sacrificial layer pattern 200a is exposed. Further, the metal layer may be patterned to form a source contact pattern 226 contacting the first channel connection pattern 222 and a drain contact pattern 228 contacting the second channel connection pattern 224.

The source contact pattern 226 may be formed on the base layer 100, and may cover the sidewalls of the sacrificial layer patterns 200a and the surface of the first channel connection pattern 222. The drain contact pattern 228 may be formed on the base layer 100, and may cover the sidewalls of the sacrificial layer patterns 200a and the surface of the second channel connection pattern 224. Further, the first channel connection pattern 222 and the source contact pattern 226 may serve as a source contact structure 230. The second channel connection pattern 224 and the drain contact pattern 228 may serve as a drain contact structure 232.

Referring to FIG. 18, the sacrificial layer patterns 200a may be selectively removed. Accordingly, the surfaces of the channel patterns 220 covered by the sacrificial layer patterns 200a may be exposed.

Referring to FIG. 19, a first gate layer 140 may be formed surrounding outer surfaces of the channel patterns 220. Even after the first gate layer 140 is formed, a space may remain between the channel patterns 220 in the vertical direction Z.

The first gate layer 140 may be a material layer for doping holes into the channel pattern 220. The first gate layer 140 may include a metal chloride. The first gate layer 140 may be formed of, for example, hafnium chloride (HfCl₄), aluminum chloride (AlCl), zirconium chloride (ZrCl), titanium chloride (TiCl), vanadium chloride (VCl₃), niobium chloride (NbCl₅), tantalum chloride (TaCl₅), etc.

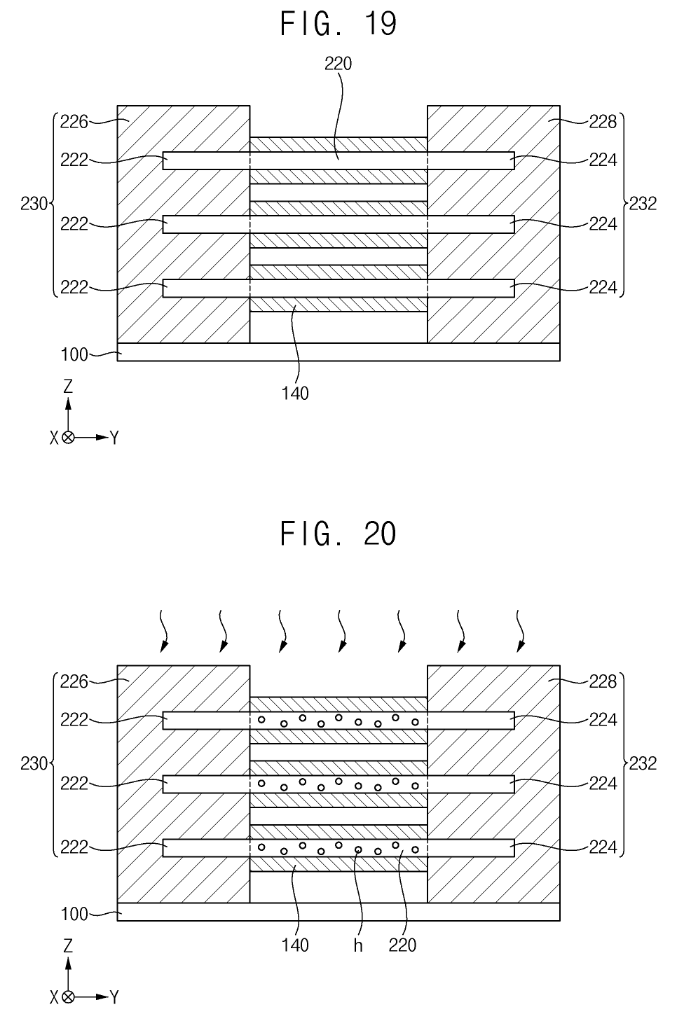

Referring to FIG. 20, a heat treatment may be performed on the first gate layer 140. At least a portion of each channel pattern 220 may be oxidized by the heat treatment process. Therefore, the channel patterns 220 may be doped with holes h.

In example embodiments, the process for forming the first gate layer 140 and the process for doping the holes h may be performed in situ.

Since the process of doping the holes h does not use a process such as a plasma doping process or an ion implantation process, damage to the channel patterns 220 may be reduced in the hole doping process.

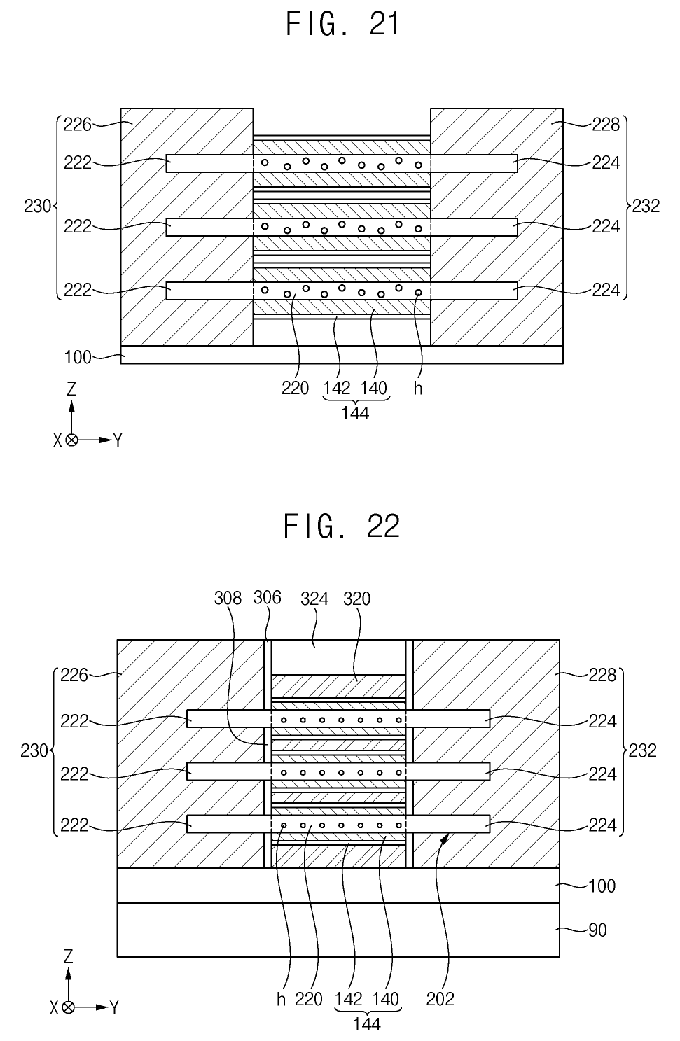

Referring to FIG. 21, a second gate layer 142 may be formed on the first gate layer 140. Even after the second gate layer 142 is formed, the space between the channel patterns 220 in the vertical direction Z may remain.

The second gate layer 142 may include a metal included in the metal chloride layer of the first gate layer 140. For example, the second gate layer 142 may be an oxide of the metal included in the metal chloride layer.

The metal oxide included in the second gate layer 142 may include, for example, hafnium oxide, aluminum oxide, zirconium oxide, titanium oxide, tantalum oxide, etc.

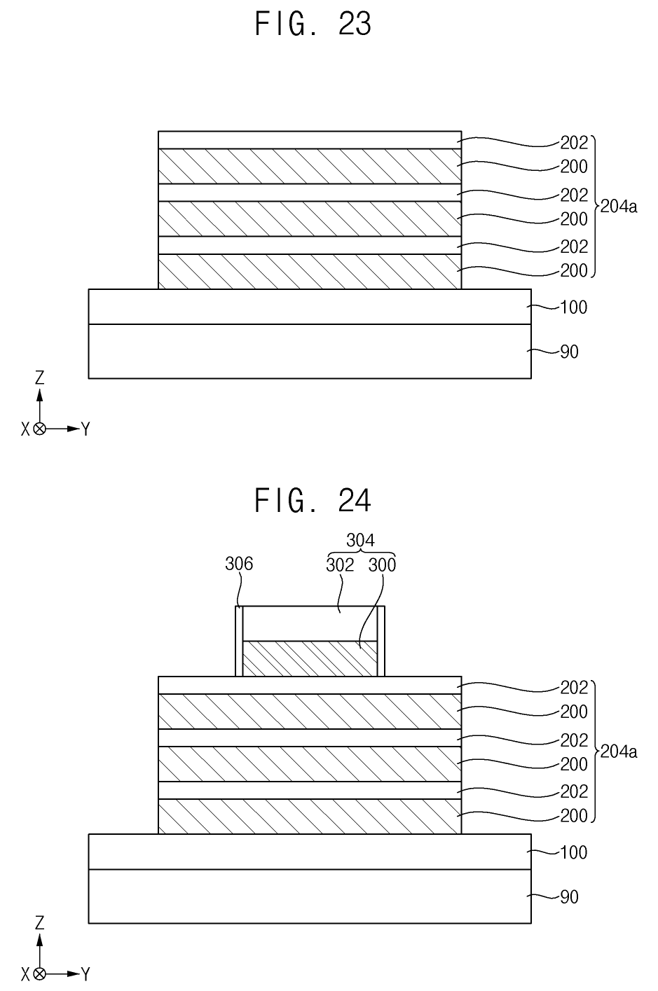

FIG. 22 is a cross-sectional view of a semiconductor device according to example embodiments.

Referring to FIG. 22, the semiconductor device may include a substrate 90, a base layer 100, a channel pattern 220, a gate structure 144, an electrode layer 320, a capping pattern 324, a first gate spacer 306, a second gate spacer 308, a source contact structure 230, and a drain contact structure 232.

The base layer 100 may be disposed on the upper surface of the substrate 90. The base layer 100 may at least partially cover an upper surface of the substrate 90.

Two-dimensional material layer patterns 202 may be disposed on the base layer 100 to be spaced apart from each other in the vertical direction Z. Each of the two-dimensional material layer patterns 202 may include the channel pattern 220, and a first channel connection pattern 222 and a second channel connection pattern 224 disposed at both ends of the channel pattern 220.

The source contact structure 230 may be formed on the base layer 100. The source contact structure 230 may include the first channel connection patterns 222 and a source contact pattern 226. The source contact pattern 226 may fill the space between the first channel connection patterns 222 that are spaced apart from each other, and may cover the surfaces of the first channel connection patterns 222. The source contact pattern 226 may include metal.

The drain contact structure 232 may be formed on the base layer 100. The drain contact structure 232may include the second channel connection patterns 224 and a drain contact pattern 228. The drain contact pattern may fill the space between the second channel connection patterns 224, and may cover the surface of the second channel connection patterns 224. The drain contact pattern 228 and the source contact pattern 226 may be formed together by the same process. Accordingly, the drain contact pattern 228 and the source contact pattern 226 may include the same metal.

The first gate spacer 306 and the second gate spacer 308 may be arranged on sidewalls of the source contact structure 230 and the drain contact structure 232 facing each other, respectively. The first gate spacer 306 may be disposed on a sidewall of the source contact pattern 226 positioned higher than an upper surface of an uppermost first channel connection pattern 222 and on a sidewall of the drain contact pattern 228 positioned higher than the upper surface of an uppermost second channel connection pattern 224. The second gate spacer 308 may be disposed on the sidewall of the source contact pattern 226 positioned lower than the lower surface of the uppermost first channel connection pattern 222 and on the sidewall of the drain contact pattern 228 positioned lower than the lower surface of the uppermost second channel connection pattern 224.

Each of the first and second gate spacers 306 and 308 may include, for example, an oxide having insulating property such as silicon oxide or a nitride having insulating property such as silicon nitride.

The channel patterns 220 may be disposed between the first and second gate spacers 306 and 308 on the sidewall of the source contact structure 230 and the first and second gate spacers 306 and 308 on the sidewall of the drain contact structure 232. The channel patterns 220 may be spaced apart from each other in the vertical direction Z. Holes h may be doped within the channel patterns 220. The holes h within the channel patterns 220 may be formed by the metal chloride of the gate structure 144. The holes h within the channel patterns 220 may be uniformly doped. In addition, the channel patterns 220 may have no defects due to the doping of the holes h.

The gate structure 144 may surround an outer surface of each of the channel patterns 220. The gate structures 144 surrounding the channel patterns 220 may be spaced apart from each other in the vertical direction Z. Each of gate structures 144 may contact portions of the first and second gate spacers 306 and 308.

The gate structure 144 may include a first gate layer 140 including the metal chloride and a second gate layer 142 including the metal oxide. The metal chloride included in the first gate layer 140 may be the same as the metal chloride layer described in the stacked structure of FIG. 1.

The metal oxide included in the second gate layer 142 may be the same as the metal oxide described in the stacked structure of FIG. 1.

The electrode layer 320 may be disposed on the gate structure 144. The electrode layer 320 may fill space between the gate structures 144 in the vertical direction Z. The capping pattern 324 may be disposed on an uppermost surface of the electrode layer 320. The capping pattern 324 may include an insulation material.

In some example embodiments, the gate structure 144 including the first gate layer 140 and the second gate layer 142 may function as a composite gate dielectric layer of a transistor. For example, both the first gate layer 140 and the second gate layer 142 may have electrically insulating properties. Through the gate structure 144, the electrode layer 320 (or gate electrode) may apply an electric field to the channel pattern 220.

The transistor may be a P-type transistor. Since each of the channel patterns is doped with holes, the transistor may have excellent mobility. Further, in the transistor, damage of the channel patterns may be decreased.

FIGS. 23 to 29 are cross-sectional views illustrating a method of manufacturing a semiconductor device according to example embodiments.

Referring to FIG. 23, a base layer 100 may be formed on a substrate 90. A sacrificial layer and a two-dimensional material layer may be alternately and repeatedly stacked on the base layer 100. The sacrificial layer may include a material having an etch selectivity with respect to the two-dimensional material layer.

Thereafter, the sacrificial layers and two-dimensional material layers may be patterned to form a first structure 204a in which preliminary sacrificial layer pattern 200 and two-dimensional material layer pattern 202 are alternately and repeatedly stacked. The preliminary sacrificial layer pattern 200 may be formed on an upper surface of the base layer 100. The preliminary sacrificial layer pattern 200 may be at least formed on a lowermost portion of the first structure 204a, and the two-dimensional material layer pattern 202 may be at least formed on an uppermost portion of the first structure 204a.

Referring to FIG. 24, a dummy gate structure (that may be referred to as a sacrificial gate structure) 304 may be formed on the base layer 100 to partially cover an upper surface and both sidewalls in the first direction X of the first structure 204a. The dummy gate structure 304 may extend in the first direction X.

Particularly, a dummy gate layer and a dummy gate mask layer covering the first structure 204a may be sequentially formed, an etching mask extending in the first direction X may be formed on the dummy gate mask layer, and the dummy gate mask layer may be etched using the etching mask to form a dummy gate mask 302. Thereafter, the dummy gate layer may be etched using the dummy gate mask 302 as an etching mask to form a dummy gate 300. The dummy gate 300 can include a material having an etching selectivity with respect to the first structure 204a. Thereafter, a first gate spacer 306 may be formed on both sidewalls in the second direction Y of the dummy gate structure 304.

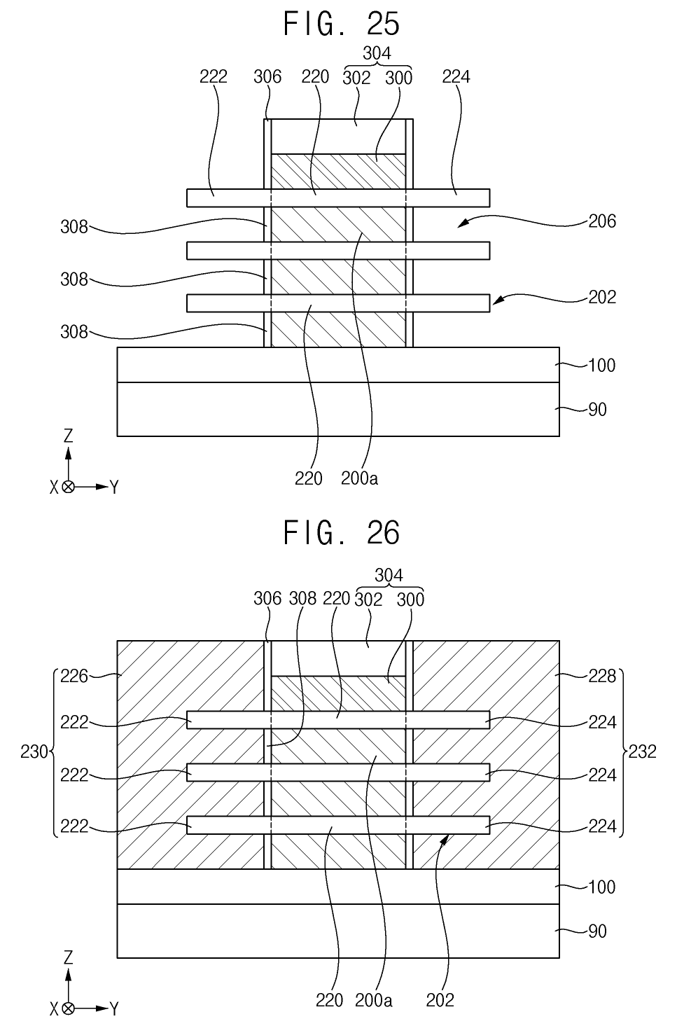

Referring to FIG. 25, the preliminary sacrificial layer pattern 200 positioned outside the first gate spacer 306 may be selectively removed to form a sacrificial layer pattern 200a.

A recess 206 may be formed between the two-dimensional material layer patterns 202 by performing the above process. Accordingly, the two-dimensional material layer patterns 202 may protrude laterally further than the sacrificial layer pattern 200a. Surfaces of both edges of the two-dimensional material layer patterns 202 may be exposed.

Thereafter, second gate spacers 308 may be formed on both sidewalls in the second direction Y of the sacrificial layer patterns 200a exposed by the recess 206.

In the two-dimensional material layer pattern, a portion covered by the sacrificial layer pattern 200a is referred to as a channel pattern 220. Further, portions of the two-dimensional material layer pattern that contact both ends in the second direction Y of the channel pattern 220 are referred to as a first channel connection pattern 222 and a second channel connection pattern 224, respectively.

Referring to FIG. 26, a metal layer may be formed on the base layer 100, outer walls of the first and second gate spacers 306 and 308, surfaces of the first channel connection pattern 222, and the second channel connection pattern 224 to fill the recesses 206. The metal layer may be planarized until an upper surface of the uppermost sacrificial layer pattern 200a is exposed. Further, the metal layer may be patterned.

Accordingly, a source contact pattern 226 contacting the first channel connection pattern 222 and a drain contact pattern 228 contacting the second channel connection pattern 224 may be formed. The source contact pattern 226 may contact the first and second gate spacers 306 and 308. The drain contact pattern 228 may contact the first and second gate spacers 306 and 308.

The first channel connection pattern 222 and the source contact pattern 226 may serve as a source contact structure 230. The second channel connection pattern 224 and the drain contact pattern 228 may serve as a drain contact structure 232.

Referring to FIG. 27, the dummy gate structure 304 may be removed. Additionally, the sacrificial layer patterns 200a may be removed. Therefore, a first opening 310 may be formed by removing the dummy gate structure 304 and the sacrificial layer patterns 200a.

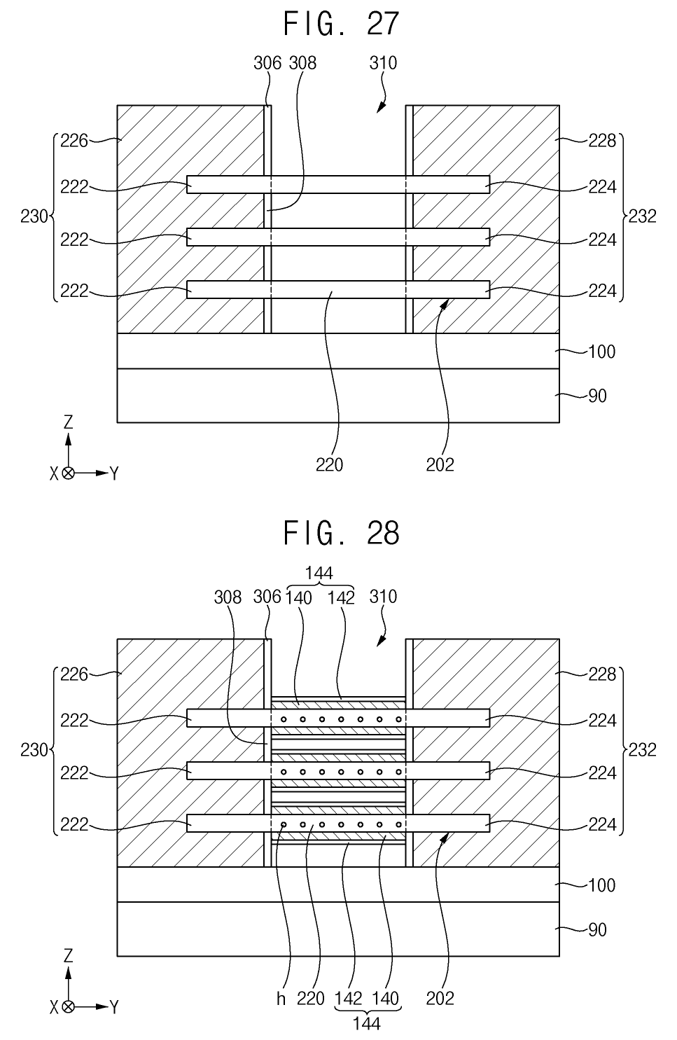

Referring to FIG. 28, a first gate layer 140 may be formed on outer surfaces of the channel patterns 220. A heat treatment may be performed on the first gate layer 140. At least a portion of each channel pattern 220 may be oxidized by the heat treatment process. Therefore, the channel patterns 220 may be doped with holes h.

In example embodiments, the process for forming the first gate layer 140 and the process for doping the holes h may be performed in situ.

A second gate layer 142 may be formed on the first gate layer 140. Even after the second gate layer 142 is formed, a space between the channel patterns 220 in the vertical direction Z may remain.

A gate structure 144 may be formed by the above process. The process for forming the gate structure 144 may be the same as that described with reference to FIGS. 19 to 21.

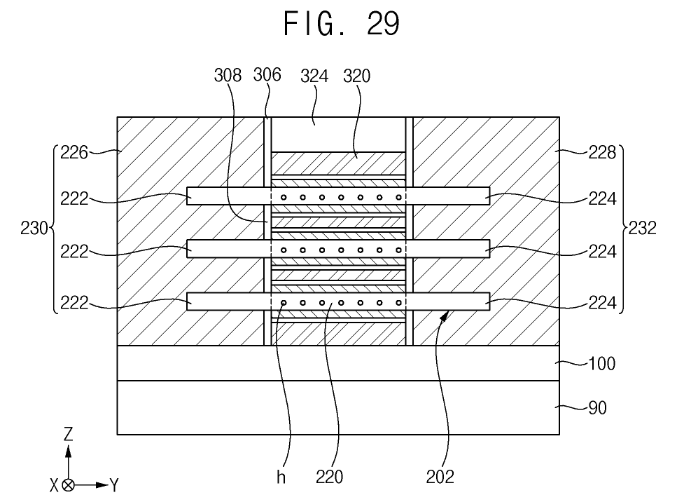

Referring to FIG. 29, an electrode layer 320 may be formed on the gate structure 144. The electrode layer 320 may fill the first opening 310. An upper portion of the electrode layer 320 may be partially removed to form an upper recess. A capping pattern 324 may be formed within the upper recess.

According to some example embodiments, there is provided a method for manufacturing a semiconductor device. The method may include forming a plurality of two-dimensional material layer patterns including two-dimensional material layers. The two-dimensional material layer patterns may be spaced apart from an upper surface of the base layer and from each other in a vertical direction perpendicular to the upper surface of the base layer. A source contact structure may be formed to fill a vertical gap of first edges of the plurality of two-dimensional material layer patterns, and the source contact structure may contact at least an upper surface and a lower surface of the first edges of the plurality of two-dimensional material layer patterns. A drain contact structure may be formed to fill a vertical gap of second edges opposite the first edges of the plurality of two-dimensional material layer patterns, and the drain contact structure may contact at least an upper surface and a lower surface of the second edge of the plurality of two-dimensional material layer patterns. A first gate layer including a metal chloride may be formed on the surfaces of the plurality of two-dimensional material layer patterns between the source contact structure and the drain contact structure. A heat treatment may be performed on the first gate layer, and thus the two-dimensional material layer pattern facing the first gate layer may be doped with holes. A second gate layer may be formed to surround the surface of the first gate layer, and the second gate layer may include at least the metal included in the first gate layer.

In example embodiments, the method may further include forming a sacrificial layer pattern between a plurality of two-dimensional material layer patterns spaced apart from each other in a vertical direction; and removing the sacrificial layer pattern after forming the source contact structure and the drain contact structure.

In example embodiments, at least a portion of the two-dimensional material layer may be oxidized by the heat treatment of the first gate layer.

In example embodiments, stacked structures including the first gate layer and the second gate layer surrounding the two-dimensional material layer patterns may be spaced apart from each other in a vertical direction.

In example embodiments, the two-dimensional material layer pattern may include graphene, black phosphorus, hexagonal boron nitride (hBN), or a transition metal dichalcogenide (TMD).

In example embodiments, the metal chloride may include a material having a reduction potential lower than a valence energy level of the two-dimensional material layer pattern.

In example embodiments, the metal chloride may include hafnium chloride (HfCl4), aluminum chloride (AlCl), zirconium chloride (ZrCl), titanium chloride (TiCl), vanadium chloride (VCl₃), niobium chloride (NbCl₅), or tantalum chloride (TaCl₅).

In example embodiments, the first gate layer may be formed using a gas phase doping, a thermal evaporation, an E-beam evaporation, a chemical vapor deposition (CVD), an atomic layer deposition (ALD), a molecular layer deposition (MLD), or a physical vapor deposition (PVD).

In example embodiments, the second gate layer may include an oxide of a metal material included in the metal chloride.

In example embodiments, the second gate layer may include hafnium oxide, aluminum oxide, zirconium oxide, titanium oxide, or tantalum oxide.

In example embodiments, the source contact structure and the drain contact structure may be formed by the same processes, and may include the same metal.

According to some example embodiments, there is provided a method for manufacturing a semiconductor device. The method may include forming a first source contact pattern and a first drain contact pattern on a base layer. A first level two-dimensional material layer pattern may be formed on an upper surface of the first source contact pattern, over an upper surface of a first trench between the first source contact pattern and the first drain contact pattern, and an upper surface of the first drain contact pattern. A second source contact pattern and a second drain contact pattern may be formed on the first-layer two-dimensional material layer pattern. A second level two-dimensional material layer pattern may be formed on an upper surface of the second source contact pattern, an upper surface of the second trench between the second source contact pattern and the second drain contact pattern, and an upper surface of the second drain contact pattern. A third source contact pattern and a third drain contact pattern may be formed on the second level two-dimensional material layer pattern. A first gate layer including a metal chloride may be formed on surfaces of a plurality of two-dimensional material layer patterns between the first to third source contact patterns and the first to third drain contact patterns. A heat treatment may be performed on the first gate layer, and thus holes may be doped in the two-dimensional material layer pattern facing the first gate layer. A second gate layer may be formed to surround the surface of the first gate layer, and the second gate layer may include at least the metal included in the first gate layer.

While the present inventive concepts have been shown and described with reference to example embodiments thereof, it will be understood by those of ordinary skill in the art that various changes in form and details may be made thereto without departing from the scope of the present inventive concepts.

What is claimed is:

1. A semiconductor device, comprising:
a base layer;
a plurality of channel regions spaced apart from an upper surface of the base layer and spaced apart from each other in a vertical direction perpendicular to an upper surface of the base layer, the plurality of channel regions including a two-dimensional material, and having p-type conductivity; and
a first gate layer and a second gate layer on the base layer,
wherein the first gate layer includes a metal chloride, and the first gate layer contacts and surrounds surfaces of the plurality of channel regions, and
wherein the second gate layer includes the same metal element as the metal chloride, and the second gate layer surrounds a surface of the first gate layer.

2. The semiconductor device of claim 1, wherein the second gate layer includes a plurality of portions respectively surrounding the plurality of channel regions, and the plurality of portions of the second gate layer are spaced apart from each other in the vertical direction in a cross-sectional view.

3. The semiconductor device of claim 1, wherein the two-dimensional material includes graphene, black phosphorus, hexagonal boron nitride or a transition metal dichalcogenide.

4. The semiconductor device of claim 1, wherein the metal chloride has a Fermi energy level lower than a valence energy level of each of the plurality of channel regions.

5. The semiconductor device of claim 1, wherein the metal chloride includes hafnium chloride, aluminum chloride, zirconium chloride, titanium chloride, vanadium chloride, niobium chloride, or tantalum chloride.

6. The semiconductor device of claim 1, wherein the second gate layer includes an oxide of a metal included in the metal chloride.

7. The semiconductor device of claim 1, wherein the second gate layer includes hafnium oxide, aluminum oxide, zirconium oxide, titanium oxide, or tantalum oxide.

8. The semiconductor device of claim 1, further comprising:
a plurality of source regions disposed on the upper surface of the base layer, each of the plurality of source regions connected to a first end of a corresponding one of the plurality of channel regions; and
a plurality of drain regions disposed on the upper surface of the base layer, each of the plurality of drain regions connected to a second end of a corresponding one of the plurality of channel regions,
wherein each of the first ends faces away from a corresponding one of the second ends.

9. The semiconductor device of claim 8, further comprising:
a source contact pattern including a plurality of portions in a cross-sectional view; and
a drain contact pattern including a plurality of portions in the cross-sectional view,
wherein the plurality of portions of the source contact pattern and the plurality of source regions are alternately and repeatedly stacked,
wherein each of the plurality of source regions and each of the plurality of channel regions includes the same material,
wherein the plurality of portions of the drain contact pattern and the plurality of drain regions are alternately and repeatedly stacked, and
wherein each of the plurality of drain regions and each of the plurality of channel regions includes the same material.

10. The semiconductor device of claim 8, further comprising:
a source contact pattern disposed on the base layer; and
a drain contact pattern disposed on the base layer,
wherein the plurality of source regions are spaced apart from each other in the vertical direction, and the source contact pattern covers an upper surface, a lower surface, and sidewalls of each of the plurality of source regions,
wherein each of the plurality of source regions includes the same material as each of the plurality of channel regions,
wherein the plurality of drain regions are spaced apart from each other in the vertical direction, and the drain contact pattern covers an upper surface, a lower surface, and sidewalls of each of the plurality of drain regions, and
wherein each of the plurality of drain regions and each of the plurality of channel regions includes the same material.

11. The semiconductor device of claim 10, wherein the source contact pattern and the drain contact pattern each include platinum (Pt), palladium (Pd), gold (Au), nickel (Ni), ruthenium (Ru), niobium (Nb), iridium (Ir), tungsten (W), molybdenum (Mo), cobalt (Co), scandium (Sc), yttrium (Y), vanadium (V), indium (In), or zinc (Zn), or a combination thereof.

12. A semiconductor device, comprising:
a base layer;
a plurality of two-dimensional material patterns spaced apart from an upper surface of the base layer and spaced apart from each other in a vertical direction perpendicular to the upper surface of the base layer, the plurality of two-dimensional material patterns including a two-dimensional material;
a source contact pattern filling a gap between the plurality of two-dimensional material patterns in the vertical direction and contacting an upper surface and a lower surface of first regions of the plurality of two-dimensional material patterns;
a drain contact pattern filling a gap between the plurality of two-dimensional material patterns and contacting an upper surface and a lower surface of second regions of the plurality of two-dimensional material patterns; and
a first gate layer and a second gate layer disposed on surfaces of the plurality of two-dimensional material patterns between the source contact pattern and the drain contact pattern,
wherein the first gate layer includes a metal chloride,
wherein the second gate layer surrounds a surface of the first gate layer,
wherein the plurality of two-dimensional material patterns facing toward the first gate layer have p-type conductivity,
wherein the metal chloride includes the same material as the second gate layer, and
wherein the first regions and the second regions of the plurality of two-dimensional material patterns are disposed on opposite sides of the first gate layer in a horizontal direction.

13. The semiconductor device of claim 12, wherein the metal chloride has a Fermi energy level lower than a valence energy level of each of the plurality of two-dimensional material patterns.

14. The semiconductor device of claim 12, wherein the metal chloride includes hafnium chloride, aluminum chloride, zirconium chloride, titanium chloride, vanadium chloride, niobium chloride, or tantalum chloride.

15. The semiconductor device of claim 12, wherein the second gate layer includes an oxide of a metal material included in the metal chloride.

16. The semiconductor device of claim 12, wherein the source contact pattern includes a plurality of portions in a cross-sectional view, and the plurality of portions of the source contact pattern are interposed between the plurality of two-dimensional material patterns in the vertical direction, and
wherein the drain contact pattern includes a plurality of portions in the cross-sectional view, and the plurality of portions of the drain contact pattern are interposed between the plurality of two-dimensional material patterns in the vertical direction.

17. The semiconductor device of claim 12,
wherein the source contact pattern is a single continuous body interposed between the plurality of two-dimensional material patterns in the vertical direction and connected to sidewalls of the two-dimensional material patterns, and
wherein the drain contact pattern is a single continuous body interposed between the plurality of two-dimensional material patterns in the vertical direction and connected to the sidewalls of the plurality of two-dimensional material patterns.

18. A semiconductor device, comprising:
a base layer;
a source contact pattern on an upper surface of the base layer;
a drain contact pattern on the upper surface of the base layer;
a plurality of active patterns having two end portions in contact with the source contact pattern and the drain contact pattern respectively, the plurality of active patterns including a two-dimensional material and spaced apart from each other in a vertical direction perpendicular to the upper surface of the base layer;
a first gate layer including a metal chloride, the first gate layer contacting and surrounding surfaces of the plurality of active patterns; and
a second gate layer surrounding a surface of the first gate layer,
wherein the source contact pattern and the drain contact pattern are disposed on opposite sides of the plurality of active patterns in a horizontal direction,
wherein the two-dimensional material has p-type conductivity, and
wherein the metal chloride and the second gate layer include the same metal element.

19. The semiconductor device of claim 18, wherein the metal chloride includes hafnium chloride, aluminum chloride, zirconium chloride, titanium chloride, vanadium chloride, niobium chloride, or tantalum chloride.

20. The semiconductor device of claim 18, wherein the second gate layer includes an oxide of a metal included in the metal chloride.
